(19) United States
(12) Patent Application Publication
(10) Pub. No.: US 2026/0181973 A1
(43) Pub. Date: Jun. 25, 2026

(54) P-TYPE BULK SILICON MEMORY DEVICE USING FEEDBACK MECHANISM

(71) Applicant: Kyonggi University Industry & Academia Cooperation Foundation, Suwon-si (KR)

(72) Inventors: Doo Hyeok LIM, Suwon-si (KR); Hak In Kim, Suwon-si (KR); Da On Kim, Suwon-si (KR)

(73) Assignee: Kyonggi University Industry & Academia Cooperation Foundation, Suwon-si (KR)

(21) Appl. No.: 19/371,377

(22) Filed: Oct. 28, 2025

(30) Foreign Application Priority Data
Dec. 24, 2024 (KR) 10-2024-0195404

(51) Int. Cl. H10D 62/10; H10B 12/00; H10D 62/83

(52) U.S. Cl. CPC H10D 62/102; H10B 12/00; H10B 12/01; H10D 62/116; H10D 62/126; H10D 62/83

(57) ABSTRACT

The present disclosure relates to a p-type bulk silicon memory device, and more particularly, to a technology that implements stable and reliable memory operation by utilizing positive feedback and negative feedback mechanisms based on a triple-well structure and a p-n junction isolation layer, and provides low power consumption and high integration density without a capacitor. In particular, the present disclosure meets the requirements of next-generation memory devices and provides solutions suitable for various electronic devices through miniaturization and high integration.

### CROSS-REFERENCE TO RELATED APPLICATION

This application claims priority to Korean Patent Application No. 10-2024-0195404, filed on Dec. 24, 2024 in the Korean Intellectual Property Office, the disclosure of which is incorporated herein by reference.

### BACKGROUND OF THE DISCLOSURE

### Field of the Disclosure

The present disclosure relates to a p-type bulk silicon memory device, and more particularly, to a memory device technology that implements stable and reliable memory operation by utilizing positive feedback and negative feedback mechanisms based on a triple-well structure and a p-n junction isolation layer, and provides low power consumption and high integration density without a capacitor.

### Description of the Related Art

Modern memory device technology has been developed with the goals of fast data access speed, high integration density, and low power consumption, and DRAM, SRAM, and NAND flash memory are being utilized in various electronic devices.

DRAM provides high integration density and fast data speed through a 1T-1C structure, but there are limitations in reducing the physical size of the capacitor, resulting in problems such as increased leakage current at high voltages and reduced data retention time.

To solve this problem, a 1T memory device utilizing a positive feedback mechanism based on an SOI (Silicon-on-Insulator) substrate has been studied, but the SOI substrate has high manufacturing cost and low thermal conductivity, which deteriorates device characteristics and makes it difficult to ensure reduced power consumption and stable operation.

Bulk silicon substrates have lower manufacturing costs compared to SOI substrates and have great potential due to their excellent compatibility with CMOS processes, but existing research has failed to effectively block leakage current, failing to solve reliability degradation and stability problems due to interference within the device or between devices.

Some technologies have attempted to compensate for these problems through epitaxial processes, but epitaxial processes are complex, have long manufacturing times, resulting in increased costs and low mass productivity. In addition, memory devices using the existing p-n-p-n structure require repeated multiple ion implantations and high-temperature heat treatment processes to reduce leakage current, which leads to process complexity and increased manufacturing costs. Therefore, there is a need for a new memory device structure that simplifies existing complex processes while effectively blocking leakage current and has high reliability and thermal stability.

### RELATED ART DOCUMENT

### Patent Document

(Patent Document 1) Korean Patent No. 2499699 “Variable Logic-in-Memory Device Using Silicon Transistor”
(Patent Document 2) Korean Patent No. 2533714 “Single Layer Polysilicon Non-Volatile Memory Cell and Memory Thereof”

### SUMMARY OF THE DISCLOSURE

Therefore, the present disclosure has been made in view of the above problems, and it is an object of the present disclosure to solve leakage current problems occurring in existing memory devices and prevent electrical interference.

It is another object of the present disclosure to provide a memory device capable of implementing stable and reliable memory operation without a capacitor.

It is still another object of the present disclosure to develop a memory device that is compatible with CMOS processes and has a simple manufacturing process.

It is yet another object of the present disclosure to minimize power consumption of the memory device and improve integration density.

It is a further object of the present disclosure to provide a wide current sensing margin capable of clearly distinguishing states of the memory device.

In accordance with an aspect of the present disclosure, the above and other objects may be accomplished by providing a p-type bulk silicon memory device comprising: a triple-well layer formed on a bulk silicon substrate, the triple-well layer comprising an n-well formed on the bulk silicon substrate, a p-well formed within the n-well, and an n-well formed again within the p-well; a p+ drain and an n+ source formed within the triple-well layer; a p-n junction isolation layer formed to eliminate leakage paths between devices and within the device, the p-n junction isolation layer comprising the p-well, the n-well, the p+ drain, and the n+ source; a LOCOS (local oxidation of silicon) layer formed in a region outside the p-n junction isolation layer; and wherein memory operation is implemented based on accumulation and extinction of electrons and holes between the p+ drain and the n+ source.

In accordance with another aspect of the present disclosure, the triple-well layer provides electrical isolation through p-n junctions such that the n+ source formed within the p-well and the n-well within the p-well are electrically isolated from each other, wherein the n-well is formed by donor ion implantation and the p-well is formed by acceptor ion implantation.

In accordance with another aspect of the present disclosure, the p+ drain is formed by implanting acceptor ions within the n-well, and wherein the p+ drain and the n+ source are configured to be electrically isolated within the triple-well layer.

In accordance with another aspect of the present disclosure, the p-n junction isolation layer is formed in association with the triple-well layer to block leakage current paths between devices and within the device.

In accordance with another aspect of the present disclosure, the LOCOS layer is formed to block leakage current paths that may be formed along a substrate surface by forming an oxide film in a region outside an active channel.

In accordance with another aspect of the present disclosure, electrons and holes form a positive feedback loop within the triple-well layer, and wherein the loop implements memory characteristics through processes of accumulation and extinction of charge carriers.

In accordance with another aspect of the present disclosure, the bulk silicon substrate comprises a p-type silicon substrate, and wherein the triple-well layer formed on the substrate forms a p-n-p-n structure to provide electrical isolation.

In accordance with another aspect of the present disclosure, a method of manufacturing a bulk silicon memory device comprises: forming an n-well by implanting donor ions on a bulk silicon substrate; forming a p-well by implanting acceptor ions within the n-well, and forming an n-well by again implanting donor ions within the p-well; forming a p region and a p+ drain by implanting acceptor ions within the n-well; forming an n+ source by implanting donor ions within the p region; forming an insulating layer covering the triple-well layer; forming a metal wiring layer on the insulating layer to transmit electrical signals; and forming a passivation layer to protect the metal wiring layer from an external environment.

In accordance with another aspect of the present disclosure, electrons and holes form a positive feedback loop within the triple-well layer, and wherein the loop implements memory characteristics through processes of accumulation and extinction of charge carriers.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a bulk silicon memory device structure in which leakage current is blocked through p-n junction isolation.

FIG. 2 is a bulk silicon memory device structure in which leakage current is blocked through LOCOS isolation.

FIG. 3 is a bulk silicon memory device structure in which leakage current is blocked through p-n junction isolation when utilizing an n-type silicon substrate.

FIG. 4 is a bulk silicon memory device structure proposed in the present disclosure.

FIG. 5 is a diagram illustrating a memory operation principle of the bulk silicon memory device of the present disclosure.

FIG. 6A is a diagram showing drain-source current (I_{DS}) characteristics according to gate-source voltage (V_{GS}) of the bulk silicon memory device of the present disclosure.

FIG. 6B is a diagram showing drain-source current (I_{DS}) characteristics according to drain-source voltage (V_{DS}) of the bulk silicon memory device of the present disclosure.

FIG. 7 is a diagram showing memory operation embodiments of the bulk silicon memory device of the present disclosure.

### DETAILED DESCRIPTION OF THE DISCLOSURE

Specific structural or functional descriptions of embodiments according to the concept of the present invention disclosed herein are merely illustrated for the purpose of describing the embodiments according to the concept of the present invention, and the embodiments according to the concept of the present invention may be implemented in various forms and are not limited to the embodiments described herein.

Since the embodiments according to the concept of the present invention may be subject to various modifications and may take various forms, the embodiments will be illustrated in the drawings and described in detail in the specification. However, this is not intended to limit the embodiments according to the concept of the present invention to specific disclosed forms, but rather to include modifications, equivalents, or alternatives that fall within the spirit and scope of the present invention.

Terms such as “first” or “second” may be used to describe various elements, but such elements should not be limited by the terms. The terms are used only to distinguish one element from another, and for example, without departing from the scope of the present invention, a first element may be designated as a second element, and similarly, a second element may be designated as a first element.

When an element is referred to as being “connected” or “coupled” to another element, it should be understood that the element may be directly connected or coupled to the other element, or intervening elements may be present. In contrast, when an element is referred to as being “directly connected” or “directly coupled” to another element, it should be understood that no intervening elements are present. Expressions describing relationships between elements, such as “between,” “directly between,” or “adjacent to,” should be interpreted in the same manner.

The terminology used in this specification is for the purpose of describing particular embodiments only and is not intended to limit the present invention. Singular forms are intended to include plural forms unless the context clearly dictates otherwise. As used herein, the terms “comprise” and “have” specify the presence of stated features, integers, steps, operations, elements, parts, or combinations thereof, but do not preclude the presence or addition of one or more other features, integers, steps, operations, elements, parts, or combinations thereof.

Unless otherwise defined, all terms used herein, including technical and scientific terms, have the same meaning as commonly understood by one of ordinary skill in the art to which this invention belongs. Terms defined in generally used dictionaries should be interpreted as having meanings consistent with their usage in the relevant technical context, and unless expressly defined in this specification, they should not be interpreted in an idealized or overly formal sense.

Hereinafter, embodiments will be described in detail with reference to the accompanying drawings. However, the scope of the patent application is not limited or restricted to such embodiments. The same reference numerals in the drawings denote the same elements.

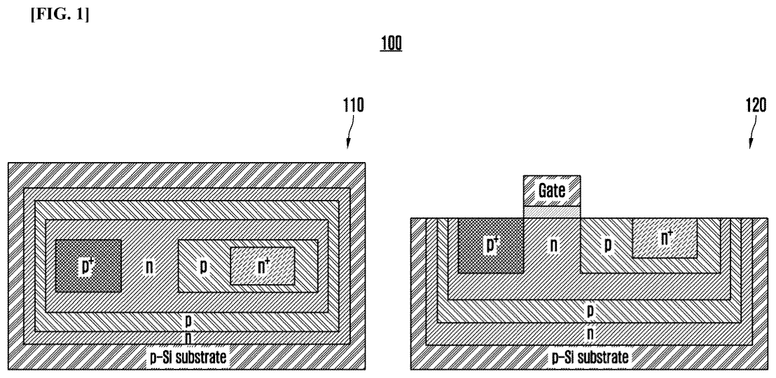

FIG. 1 illustrates a bulk silicon memory device structure 100 in which leakage current is blocked through p-n junction isolation.

The structure of the p-type bulk silicon memory device denoted by reference numeral 110 is characterized by forming a triple-well having a p-n-p-n structure in which an n-well and an n+ region are isolated from each other through a p region in an active channel region of a bulk silicon substrate, thereby eliminating leakage paths through electrical isolation by p-n junctions.

In the p-type bulk silicon memory device 120 of FIG. 1, a triple-well layer is formed, comprising an n-well formed on a bulk silicon substrate, a p-well formed within the n-well, and an n-well formed again within the p-well.

A p+ drain and an n+ source are formed within the triple-well layer, and a p-n junction isolation layer is formed to eliminate leakage paths between devices and within the device, including the p region, the n-well, the p+ drain, and the n+ source.

A LOCOS layer is formed in a region outside the p-n junction isolation layer, and memory operation is implemented through accumulation and extinction of electrons and holes between the p+ drain and the n+ source.

The bulk silicon substrate is composed of a p-type silicon semiconductor and provides a foundation for the memory device. The bulk silicon substrate provides a physical base for forming the triple-well layer and supports stable operation of the memory device.

The triple-well layer is formed on the bulk silicon substrate and comprises an n-well, a p-well, and an n-well formed again within the p-well. The n-well is formed by implanting donor ions (dose: 8×10¹² cm⁻², energy: 160 keV), provides electrical isolation between the p-type silicon substrate and the p-well, and blocks leakage current.

The p-well is formed by implanting acceptor ions (dose: 3×10³ cm⁻², energy: 110 keV), provides electrical isolation from the n-well, and controls the flow of charge. The n-well formed within the p-well is implemented through additional donor ion implantation, prevents electrical interference, and secures the stability of the memory device. The triple-well layer provides electrical isolation through p-n junctions and plays an important role in eliminating current leakage paths that may occur between devices and within the device.

The p+ drain and the n+ source are each formed within the triple-well layer. The p+ drain is formed by implanting acceptor ions at high concentration within the p-well (dose: 1×10¹⁵ cm⁻², energy: 30 keV), accumulates charge carriers during memory operation, and contributes to implementing memory characteristics.

The n+ source is formed by implanting donor ions at high concentration (dose: 1×10¹⁵ cm⁻², energy: 30 keV), supports the extinction of charge carriers, and controls the movement of charge. The p+ drain and the n+ source are designed to be electrically isolated within the triple-well layer, which prevents electrical interference between devices and ensures stable operation of the memory device.

The p-n junction isolation layer includes the p+ drain, the n+ source, the p region, and the n-well, and is formed to eliminate leakage current paths that may occur between devices and within the device. The p-n junction isolation layer works in association with the triple-well layer to provide electrical isolation and prevents current from flowing through unintended paths. The p-n junction limits current flow and improves the reliability of the memory device.

The gate structure is formed on top of the triple-well layer and implements the operational characteristics of the memory device. The gate controls the accumulation and extinction of electrons and holes between the p+ drain and the n+ source, and implements memory characteristics through a positive feedback mechanism. The gate transmits electrical signals to control the movement of charge carriers and serves as a key element of memory operation.

The triple-well layer and the p-n junction isolation layer effectively block leakage current between devices and within the device. This mechanism prevents current from flowing through unintended paths and ensures operational stability of the memory device. The elimination of leakage current improves the reliability of the memory device and minimizes power consumption.

The structure of FIG. 1 implements memory operation based on the accumulation and extinction of electrons and holes. The p+ drain and the n+ source form a positive feedback loop to repeatedly perform processes of accumulation and extinction of charge carriers. This mechanism enables the memory device to operate without a capacitor and improves the integration density of the device.

A method of manufacturing a p-type bulk silicon memory device comprises forming an n-well by implanting donor ions on a bulk silicon substrate. Thereafter, a p-well is formed by implanting acceptor ions within the n-well, and an n-well is formed by again implanting donor ions within the p-well. The method includes forming a p region and a p+ drain by implanting acceptor ions within the n-well, forming an n+ source by implanting donor ions within the p region, forming an insulating layer covering the triple-well layer, forming a metal wiring layer on the insulating layer to transmit electrical signals, and forming a passivation layer to protect the metal wiring layer from an external environment.

During the manufacturing process, electrons and holes form a positive feedback loop within the triple-well layer, and this loop implements memory characteristics through processes of accumulation and extinction of charge carriers.

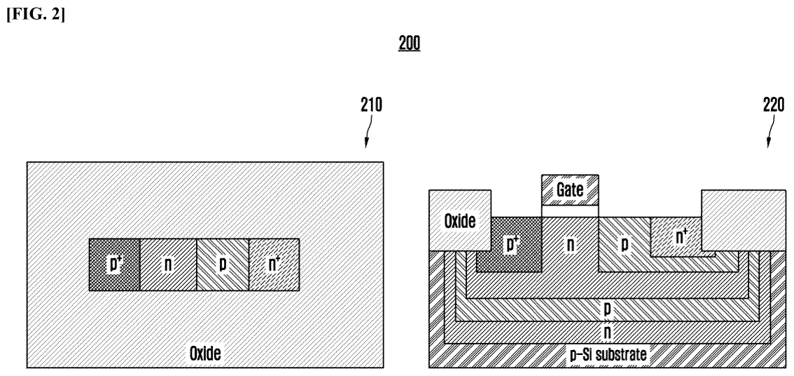

FIG. 2 illustrates a bulk silicon memory device structure 200 in which leakage current is blocked through LOCOS (Local Oxidation of Silicon) isolation.

In the present disclosure, as shown by reference numeral 210, regions other than the active channel in the bulk silicon substrate are subjected to a LOCOS process to eliminate leakage paths that may flow through the substrate surface.

Specifically, in the structure 210 of the p-type bulk silicon memory device, leakage paths occurring at the substrate surface may be eliminated through a LOCOS (Local Oxidation of Silicon) process for regions other than the active channel region in the bulk silicon substrate.

The LOCOS process forms an oxide layer on the silicon surface to block paths through which leakage current may flow.

In the LOCOS process, oxidation of the silicon surface is induced to form an oxide film. In this process, the oxide film has electrically insulating properties and blocks charge movement. In addition, the oxide film formed outside the active channel region prevents leakage of electrical signals and suppresses unnecessary current flow.

In the LOCOS process, oxidation of the silicon surface is induced to form an oxide film. In this process, the oxide film has electrically insulating properties and blocks charge movement. In addition, the oxide film formed outside the active channel region prevents leakage of electrical signals and suppresses unnecessary current flow.

The present disclosure may completely eliminate leakage paths of the device physically and electrically by combining the triple-well structure and the LOCOS process. As a result, power consumption may be reduced and device performance may be significantly improved.

Referring to reference numeral 220, the p-type bulk silicon memory device 200 is designed to prevent electrical interference between devices and within the device and effectively block leakage current by forming a LOCOS layer on the bulk silicon substrate. The bulk silicon substrate 200 is composed of a p-type silicon semiconductor and provides a foundation for the memory device. The bulk silicon substrate forms a physical base that accommodates the LOCOS layer and the triple-well structure, and supports stable operation of the memory device.

The LOCOS layer is formed on the bulk silicon substrate and blocks leakage current paths by forming an oxide film in regions outside the active channel. The LOCOS layer is designed to prevent current that may flow through the substrate surface and enhances electrical isolation between devices.

Below the LOCOS layer, a p region, an n-well, and a p+ drain and an n+ source are formed. The n-well is formed by implanting donor ions and provides electrical isolation between the p-type silicon substrate and the p-well.

The p-well serves as part of the triple-well layer to prevent electrical interference that may occur between devices. The n-well is formed by implanting donor ions, provides electrical isolation from the p-well, and controls the flow of charge. The n-well ensures electrical separation of the p+ drain and the n+ source.

The p+ drain is formed within the n-well by implanting acceptor ions at high concentration and accumulates charge carriers during memory operation.

The p+ drain is a key component of the memory device and plays an important role in implementing memory characteristics. The n+ source is formed within the p region by implanting donor ions at high concentration, supports the extinction of charge carriers, and controls the movement of charge. The n+ source completes the electrical operation of the memory device together with the p+ drain.

The gate structure is formed on the LOCOS layer and controls the movement of electrons and holes between the p+ drain and the n+ source. The gate plays an essential role in implementing operational characteristics of the memory device and repeatedly performs accumulation and extinction of electrons and holes through a positive feedback mechanism.

The gate transmits electrical signals to support stable and efficient operation of the memory device. The LOCOS isolation mechanism may prevent electrical interference that may occur between devices and within the device. The mechanism effectively eliminates leakage current by forming an oxide film in regions outside the active channel and prevents current from flowing through unintended paths. LOCOS isolation is fully compatible with bulk silicon substrates and CMOS processes, and may increase the integration density of memory devices and reduce power consumption.

In conclusion, the leakage current blocking mechanism through LOCOS isolation presented in FIG. 2 may eliminate electrical interference and improve the stability and reliability of the memory device by combining with the p region, n-well, p+ drain, n+ source, and gate structure formed on the bulk silicon substrate.

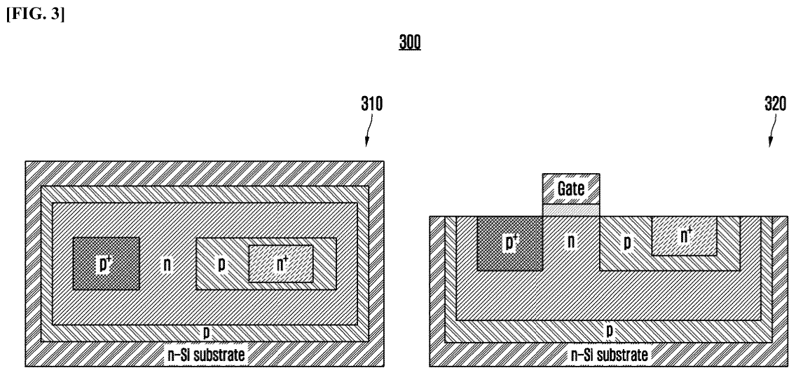

FIG. 3 illustrates a bulk silicon memory device structure 300 in which leakage current is blocked through p-n junction isolation when utilizing an n-type silicon substrate.

The bulk silicon memory device of the present disclosure is fabricated on a p-type semiconductor substrate, and when the bulk silicon memory device is fabricated on an n-type silicon substrate, as shown in FIG. 3, a p-well is formed in the substrate and an n-well is formed within the p-well. By forming the p-well to surround the n+ source such that the n-well and the n+ source are not connected to each other, and forming a p-n-p-n structure within the triple-well, electrical isolation by p-n junctions is possible.

The structure of FIG. 3 is designed to eliminate leakage current paths within devices and between devices and prevent electrical interference by forming a triple-well layer and a p-n-p-n structure based on an n-type silicon substrate.

The n-type silicon substrate forms the foundation of the bulk silicon memory device and provides a physical base for constructing the triple-well layer.

A p-well and an n-well are sequentially formed on the n-type silicon substrate. The p-well is formed by implanting acceptor ions and is designed to be electrically isolated from the n-type silicon substrate. The n-well is formed within the p-well and is formed by implanting donor ions. The n-well provides electrical isolation from the p-well and controls the flow of charge.

A p+ drain and an n+ source are each formed within the triple-well layer. The p+ drain is formed by implanting acceptor ions at high concentration and accumulates charge carriers during memory device operation.

The n+ source is formed by implanting donor ions at high concentration, supports the extinction of charge carriers, and controls the movement of charge. The p+ drain and the n+ source are included in a p-n-p-n structure formed within the p-well and the n-well, and are configured to be electrically isolated.

The p-n junction isolation layer is formed between the p+ drain, the n+ source, the p-well, and the n-well to block leakage current paths that may occur between devices and within the device. The p-n junction isolation layer works in association with the triple-well layer to provide electrical isolation, prevents electrical interference between devices, and ensures stable operation of the memory device.

In addition, the p-n junction isolation layer increases the electrical reliability of the memory device and prevents current from flowing through unintended paths.

The gate structure is formed on top of the triple-well layer and controls the movement of electrons and holes between the p+ drain and the n+ source. The gate repeatedly performs accumulation and extinction of electrons and holes through a positive feedback mechanism and implements operational characteristics of the memory device.

The gate transmits electrical signals to support stable and efficient operation of the memory device.

The triple-well layer formed on the n-type silicon substrate forms a p-n-p-n structure and enhances electrical isolation of the memory device. This structure implements memory operation based on accumulation and extinction of charge carriers and effectively controls the flow of current. In addition, the p-n junction isolation layer eliminates leakage current, minimizes electrical interference, and ensures the reliability of the memory device.

In conclusion, FIG. 3 may block leakage current, enhance the stability of the memory device, and eliminate electrical interference between devices through the triple-well layer and the p-n-p-n structure formed on the n-type silicon substrate.

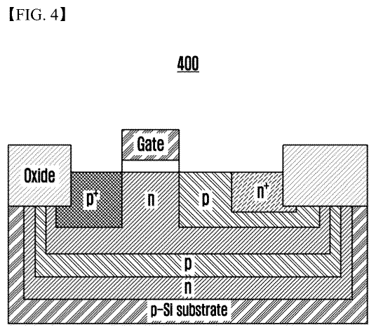

FIG. 4 illustrates a bulk silicon memory device structure 400 proposed in the present disclosure.

As shown in FIG. 4, when a triple-well is formed in a bulk silicon substrate and the energy band of the channel region is formed in a p-n-p-n structure, the hysteresis phenomenon occurring within the device due to a positive feedback loop phenomenon may be utilized as memory characteristics.

The structure of FIG. 4 includes a triple-well layer, a p-n junction isolation layer, a p+ drain, an n+ source, a gate structure, and an oxide film based on a bulk silicon substrate (p-Si substrate), and ensures stable and efficient operation of the memory device.

The bulk silicon substrate is composed of p-type silicon and forms the foundation of the memory device. The bulk silicon substrate provides a physical base for accommodating the triple-well layer and the p-n junction isolation layer, and is designed as a substrate having both thermal stability and economic efficiency.

An oxide film formed through a LOCOS (Local Oxidation of Silicon) process is additionally formed on the bulk silicon substrate.

The triple-well layer is formed on the bulk silicon substrate and comprises an n-well, a p-well, and again an n-well. The n-well is formed by implanting donor ions, and the n-well provides electrical isolation from the bulk silicon substrate and the p-well and may prevent current leakage.

The p-well is formed by implanting acceptor ions, and the p-well provides electrical isolation from the n-well and stably controls current flow during memory operation. An n-well is additionally formed within the p-well by implanting donor ions, and the inner n-well prevents electrical interference and enhances the stability of the memory device within the triple-well layer.

The p+ drain and the n+ source are each formed within the triple-well layer, and the p+ drain is formed by implanting acceptor ions at high concentration. The p+ drain accumulates charge carriers during memory operation and operates as a key component of the memory device. The n+ source is formed by implanting donor ions at high concentration, and the n+ source supports the extinction of charge carriers and controls charge movement to enable operation of the memory device.

The p-n junction isolation layer is formed between the p+ drain, the n+ source, the p region, and the n-well, and may prevent electrical interference between devices and within the device.

The p-n junction isolation layer combines with the triple-well layer to block leakage current paths and provides electrical stability between devices. In addition, the isolation layer prevents current from flowing through unintended paths and increases the reliability of the memory device.

The gate structure is formed on top of the triple-well layer and controls the movement of electrons and holes between the p+ drain and the n+ source. The gate is an essential component for implementing operational characteristics of the memory device and repeatedly performs processes of accumulation and extinction of charge carriers through a positive feedback mechanism. The gate controls electrical signals of the memory device and supports stable and efficient memory operation.

The oxide film is formed on the bulk silicon substrate through a LOCOS process and blocks leakage current paths in regions outside the active channel. The oxide film enhances electrical isolation to eliminate electrical interference between devices and improves the stability of the memory device.

The structure shown in FIG. 4 ensures stable operation of the memory device by including the triple-well layer, the p-n junction isolation layer, the p+ drain, the n+ source, the gate structure, and the oxide film.

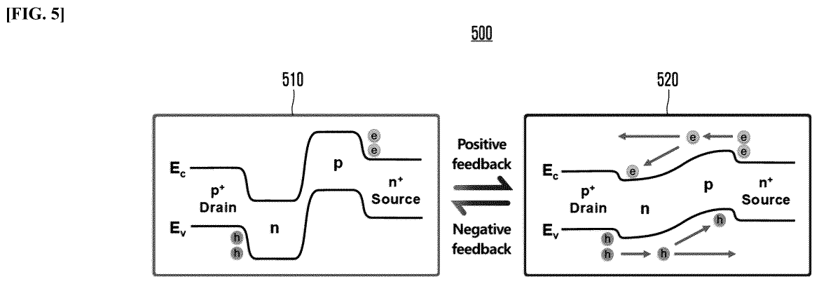

FIG. 5 is a diagram 500 illustrating a memory operation principle of the bulk silicon memory device of the present disclosure.

As shown in FIG. 5, the bulk silicon memory device exhibits memory characteristics due to a feedback loop mechanism in which electrons and holes are accumulated or extinguished in potential wells, and has a triple-well structure such that interference between devices does not occur.

The memory device is based on a p-n-p-n structure and implements memory operation by controlling the movement, accumulation, and extinction of electrons and holes. The operation principle of the memory device includes a positive feedback mechanism and a negative feedback mechanism, through which the memory device provides stable and reliable operation.

Reference numeral 510 represents a process in which electrons and holes are each accumulated in potential wells. The bulk silicon memory device includes a p-n-p-n structure composed of a p+ drain, an n region, a p region, and an n+ source formed within the triple-well layer.

Electrons move from the n+ source to the n region and are accumulated. Holes move from the p+ drain to the p region and are accumulated. The process is based on a positive feedback mechanism, and as the accumulation of charge carriers increases, more charge carriers are generated to increase the operating speed of the memory device.

In the bulk silicon memory device, current flow is controlled by a potential energy barrier while charge carriers are being accumulated. In the structure, holes move from the p region to the n+ source, and electrons move from the n region toward the p+ drain. The process enhances operational stability of the memory device through interaction between charge carriers.

Reference numeral 520 represents a process in which accumulated charge carriers are extinguished.

The negative feedback mechanism induces extinction of electrons and holes, and thereby stably controls current flow. Electrons in the n region and holes in the p region are extinguished due to recombination, and the accumulated charges disappear and prevent current from flowing. The mechanism ensures the reliability of the device.

The positive feedback mechanism maintains the “on” state of the memory device and generates a strong signal through high charge carrier accumulation. Conversely, the negative feedback mechanism removes accumulated charge in the “off” state and completely blocks current flow. The two mechanisms work complementarily to enable efficient and stable operation of the memory device.

The bulk silicon memory device may implement memory operation without a capacitor by utilizing these feedback mechanisms. The triple-well layer provides electrical isolation by p-n junctions and blocks leakage current within the device and between devices. The movement of electrons and holes between the p+ drain and the n+ source is controlled by positive feedback loops and negative feedback loops, which optimizes the electrical characteristics of the memory device.

FIG. 5 explains in detail the processes of accumulation and extinction of charge carriers through the operation principle of the bulk silicon memory device, and thereby secures the stability and reliability of the memory device. The structure reduces power consumption, maximizes compatibility with CMOS processes, and enables implementation of high-speed and high-performance memory devices. The memory device of the present disclosure provides efficient and stable memory characteristics based on the movement and control of charge carriers.

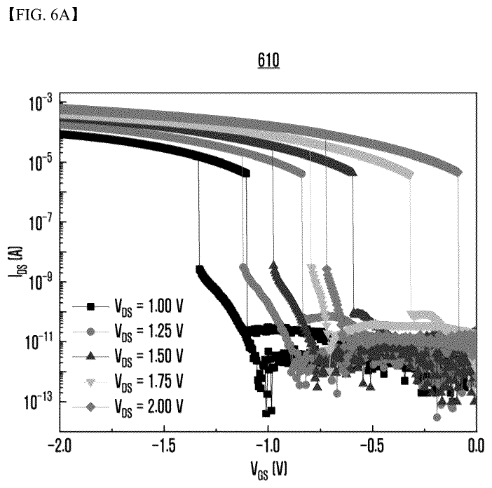

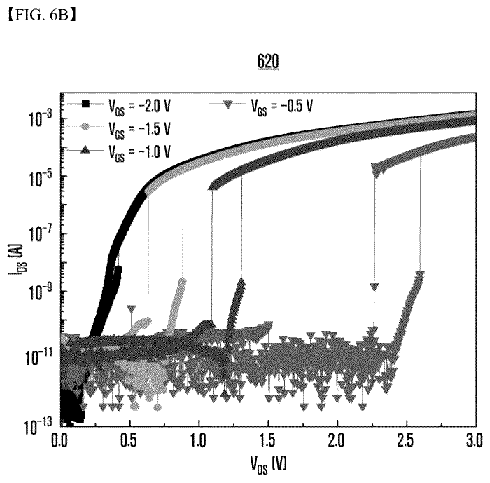

FIGS. 6A and 6B explain in detail embodiments showing memory characteristics based on the relationship between voltage and current in the bulk silicon memory device of the present disclosure.

In particular, FIG. 6A shows drain-source current (I_{DS}) characteristics 610 according to gate-source voltage (V_{GS}), and FIG. 6B shows drain-source current (I_{DS}) characteristics 620 according to drain-source voltage (V_{DS}).

FIG. 6A shows how the drain-source current (I_{DS}) changes as the gate-source voltage (V_{GS}) varies under various drain-source voltage (V_{DS}) conditions.

The drain-source voltage (V_{DS}) is set to 1.00V, 1.25V, 1.50V, 1.75V, and 2.00V, with the X-axis representing the gate-source voltage (V_{GS}) and the Y-axis representing the drain-source current (I_{DS}) on a logarithmic scale.

In the bulk silicon memory device, current is amplified by a positive feedback mechanism within the p-n-p-n structure, and when the gate-source voltage (V_{GS}) decreases below a specific threshold value, the drain-source current (I_{DS}) exhibits a switching operation in which it decreases sharply.

This is related to the process in which electrons and holes accumulated in the potential wells are removed and extinguished. Under high drain-source voltage (V_{DS}) conditions, the drain-source current (I_{DS}) maintains relatively higher values, which is because the positive feedback mechanism is further activated.

FIG. 6B shows how the drain-source current (I_{DS}) changes as the drain-source voltage (V_{DS}) varies under various gate-source voltage (V_{GS}) conditions. The gate-source voltage (V_{GS}) is set to −2.0V, −1.5V, −1.0V, and −0.5V, with the X-axis representing the drain-source voltage (V_{DS}) and the Y-axis representing the drain-source current (I_{DS}) on a logarithmic scale.

As the drain-source voltage (V_{DS}) increases, the drain-source current (I_{DS}) increases nonlinearly due to the positive feedback mechanism, and exhibits characteristics in which the current saturates above a specific voltage.

In this process, the positive feedback loop accelerates the accumulation of charge carriers to maintain high current flow. As the gate-source voltage (V_{GS}) decreases, the rate of increase of the drain-source current (I_{DS}) decreases.

The positive feedback mechanism in the present disclosure enables clear distinction between “on” and “off” memory operation states through control of gate voltage and drain voltage. These characteristics enable stable memory operation without a capacitor and may be implemented through a simpler structure and process compared to conventional DRAM and SRAM.

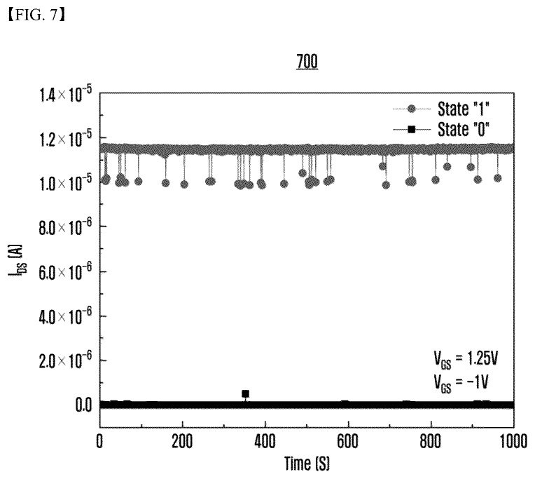

FIG. 7 is an embodiment 700 of memory operation of the bulk silicon memory device of the present disclosure.

Specifically, FIG. 7 shows how the drain-source current (I_{DS}) changes over time while the bulk silicon memory device of the present disclosure maintains memory operation states of state ‘1’ and state ‘0’ under specific conditions.

The graph in FIG. 7 shows the results of measuring operational stability of the memory device with the drain-source voltage (V_{DS}) set to 1.25V and the gate-source voltage (V_{GS}) set to −1V.

In the results of FIG. 7, state ‘1’ represents a state in which the bulk silicon memory device operates based on a positive feedback mechanism, and charge carriers are accumulated in the p+ drain and the n region to maintain a high drain-source current (I_{DS}). In this state, the drain-source current (I_{DS}) continuously maintains a value of approximately 1.0×10⁻⁵A or higher, and no significant fluctuation occurs over time. This demonstrates that the memory device may operate stably in the “on” state and shows the effect of the charge carrier accumulation mechanism.

State ‘0’ represents a state in which the bulk silicon memory device extinguishes accumulated charge carriers through a negative feedback mechanism and minimizes the drain-source current (I_{DS}).

The drain-source current (I_{DS}) decreases to 1.0×10⁻⁶A or less and remains stable over time. This demonstrates that the memory device maintains the “off” state and may minimize power consumption. The low I_{DS} value shown in state ‘0’ demonstrates the effect of the p-n junction isolation layer and the triple-well structure that minimize current leakage.

The difference in drain-source current (I_{DS}) between state ‘1’ and state ‘0’ observed in the graph of FIG. 7 means that the memory device provides a wide current sensing margin. These characteristics enable clear distinction between states of the memory device and provide high reliability. The memory device may implement memory characteristics solely through the movement and accumulation mechanism of charge carriers without a capacitor.

These memory characteristics of the bulk silicon memory device are possible due to the harmonious operation of the positive feedback mechanism and the negative feedback mechanism based on the p-n-p-n structure. In state ‘1’, accumulation of charge carriers amplifies current flow, and in state ‘0’, extinction of charge carriers blocks current. The mechanism increases the electrical reliability of the memory device and ensures stability.

In conclusion, FIG. 7 demonstrates that the bulk silicon memory device may stably maintain state ‘1’ and state ‘0’ over time. These results indicate that the bulk silicon memory device has excellent characteristics as a next-generation memory device having low power consumption, high integration density, and compatibility with CMOS processes.

Ultimately, by using the present disclosure, it is possible to implement a memory device composed of 1T by utilizing a positive feedback mechanism without a capacitor in the existing 1T-1C DRAM structure.

Stable memory operation is possible by blocking leakage current flowing to the bulk silicon substrate.

It is compatible with CMOS processes to enable improvement in integration density and reduction in power consumption, and the process is easy as it utilizes a bulk silicon substrate and does not require complex processes such as epitaxy.

In addition, by using the present disclosure, processing speed may be increased through characteristics of a wide memory operation window and a wide current sensing margin.

According to one embodiment, leakage current occurring between memory devices and within the device may be effectively eliminated by utilizing a triple-well structure and a p-n junction isolation layer.

According to one embodiment, stable memory operation may be implemented without a capacitor through positive feedback and negative feedback mechanisms.

According to one embodiment, complexity of the manufacturing process may be reduced and economic efficiency may be improved through high compatibility with CMOS processes.

According to one embodiment, power consumption of the memory device may be reduced and high integration density may be achieved.

According to one embodiment, reliability of the memory device may be maximized by providing a wide current sensing margin between state ‘1’ and state ‘0’.

As described above, although the embodiments have been described with reference to limited drawings, those skilled in the art will appreciate that various modifications and variations are possible from the above description. For example, appropriate results may be achieved even if the described techniques are performed in an order different from the described method, and/or components of the described system, structure, device, circuit, etc. are combined or combined in a form different from the described method, or are replaced or substituted by other components or equivalents.

Therefore, other implementations, other embodiments, and equivalents to the claims also fall within the scope of the claims described below.

What is claimed is:

1. A p-type bulk silicon memory device comprising:
a triple-well layer formed on a bulk silicon substrate, the triple-well layer comprising an n-well formed on the bulk silicon substrate, a p-well formed within the n-well, and an n-well formed again within the p-well;
a p+ drain and an n+ source formed within the triple-well layer;
a p-n junction isolation layer formed to eliminate leakage paths between devices and within the device, the p-n junction isolation layer comprising the p-well, the n-well, the p+ drain, and the n+ source;
a LOCOS (local oxidation of silicon) layer formed in a region outside the p-n junction isolation layer; and
wherein memory operation is implemented based on accumulation and extinction of electrons and holes between the p+ drain and the n+ source.

2. The p-type bulk silicon memory device of claim 1, wherein the triple-well layer provides electrical isolation through a p-n junction such that the n+ source formed within the p-well and the n-well within the p-well are electrically isolated from each other, wherein the n-well is formed by donor ion implantation and the p-well is formed by acceptor ion implantation.

3. The p-type bulk silicon memory device of claim 1, wherein the p+ drain is formed by implanting acceptor ions within the n-well, and wherein the p+ drain and the n+ source are configured to be electrically isolated within the triple-well layer.

4. The p-type bulk silicon memory device of claim 1, wherein the p-n junction isolation layer is formed in association with the triple-well layer to block leakage current paths between devices and within the device.

5. The p-type bulk silicon memory device of claim 1, wherein the LOCOS layer is formed to block leakage current paths that may be formed along a substrate surface by forming an oxide film in a region outside an active channel.

6. The p-type bulk silicon memory device of claim 1, wherein electrons and holes form a positive feedback loop within the triple-well layer, and wherein the loop implements memory characteristics through processes of accumulation and extinction of charge carriers.

7. The p-type bulk silicon memory device of claim 1, wherein the bulk silicon substrate comprises an n-type silicon substrate, and wherein the triple-well layer formed on the substrate forms a p-n-p-n structure to provide electrical isolation.

8. A method of manufacturing a bulk silicon memory device, the method comprising:
forming an n-well by implanting donor ions on a bulk silicon substrate;
forming a p-well by implanting acceptor ions within the n-well, and forming an n-well by again implanting donor ions within the p-well;
forming a p region and a p+ drain by implanting acceptor ions within the n-well;
forming an n+ source by implanting donor ions within the p region;
forming an insulating layer covering the triple-well layer;
forming a metal wiring layer on the insulating layer to transmit electrical signals; and
forming a passivation layer to protect the metal wiring layer from an external environment.

9. The method of claim 8, wherein electrons and holes form a positive feedback loop within the triple-well layer, and wherein the loop implements memory characteristics through processes of accumulation and extinction of charge carriers.

10. A p-type bulk silicon memory device structure comprising a triple-well having a p-n-p-n structure in which an n-well and an n+ region are isolated from each other through a p region in an active channel region of a bulk silicon substrate, wherein the triple-well is formed to eliminate leakage paths through electrical isolation by p-n junctions.

11. The p-type bulk silicon memory device structure of claim 10, wherein leakage paths occurring at a substrate surface are eliminated through a LOCOS (Local Oxidation of Silicon) process for regions other than the active channel region in the bulk silicon substrate.
